(19) United States
(12) Patent Application Publication
(10) Pub. No.: US 2024/0224623 A1
(43) Pub. Date: Jul. 4, 2024

(54) ELECTROLUMINESCENCE DISPLAY

(71) Applicant: LG Display Co., Ltd., Seoul (KR)

(72) Inventor: Hyeongjun LIM, Paju-si (KR)

(73) Assignee: LG Display Co., Ltd., Seoul (KR)

(21) Appl. No.: 18/502,432

(22) Filed: Nov. 6, 2023

(30) Foreign Application Priority Data
Dec. 30, 2022 (KR) 10-2022-0190573

(51) Int. Cl. H10K 59/124; H10K 59/122

(52) U.S. Cl. CPC H10K 59/124; H10K 59/122

(57) ABSTRACT

An electroluminescence display can include a first pixel disposed at 1^{st} row-1^{st} column, a second pixel disposed at 1^{st} row-2^{nd} column, a third pixel disposed at 2^{nd} row-1^{st} column, and a fourth pixel disposed at 2^{nd} row-2^{nd} column, on a substrate. The display can further include a first vertical trench disposed between the first pixel and the second pixel, and a second vertical trench disposed between the third pixel and the fourth pixel. Also, the display can further include a first horizontal trench disposed between the first pixel and the third pixel, a second horizontal trench disposed between the second pixel and the fourth pixel, and an induction electrode disposed at an intersection portion. Further, the first vertical trench and the second vertical trench face each other, and the first horizontal trench and the second horizontal trench face each other.

### CROSS-REFERENCE TO RELATED APPLICATIONS

This application claims priority to Korean Patent Application No. 10-2022-0190573 filed in the Republic of Korea, on Dec. 30, 2022, the entirety of which is hereby incorporated by reference into the present application as if fully set forth herein.

### BACKGROUND

### Field of the Invention

The present disclosure relates to an electroluminescence display having a structure that prevents the lateral (or horizontal) leakage current occurring between neighboring pixels.

### Discussion of the Related Art

In particular, the electroluminescent display, which is a self-luminous display, has a structure in which a plurality of pixel areas including light emitting diodes are arranged. As the density of pixels increases, the distance between pixels is reduced and the pixels are packed closer together, and distortion of pixel information can occur due to the lateral current leakage between adjacent pixels. Accordingly, there exists a need for an electroluminescence display having a structure that is capable of suppressing or preventing lateral leakage current between neighboring pixels, in order to ensure excellent image quality and reduce power consumption.

### SUMMARY OF THE DISCLOSURE

The purpose of the present disclosure, as for solving the problems described above, is to provide an electroluminescence display device (or light emitting display device) that has a high pixel density and can prevent or minimize display quality deterioration due to lateral leakage current between neighboring pixels, as the distance between pixels narrows.

The purpose of some embodiments of the present disclosure is to provide a structure that prevents or minimizes image quality distortion of a light-emitting display device by blocking the lateral leakage current in the horizontal and vertical directions of the pixel in a plan view.

The purpose of some embodiments of the present disclosure is to provide a light emitting display device having a structure which prevents lateral leakage current occurring in vertex area of pixels in a plan view.

In order to accomplish the above mentioned purposes of the present disclosure, an electroluminescence display according to the present disclosure includes a first pixel disposed at 1^{st} row-1^{st} column, a second pixel disposed at 1^{st} row-2^{nd} column, a third pixel disposed at 2^{nd} row-1^{st} column, and a fourth pixel disposed at 2^{nd} row-2^{nd} column, on a substrate; a first vertical trench disposed between the first pixel and the second pixel; a second vertical trench disposed between the third pixel and the fourth pixel; a first horizontal trench disposed between the first pixel and the third pixel; a second horizontal trench disposed between the second pixel and the fourth pixel; and an induction electrode disposed at an intersection portion where the first vertical trench and the second vertical trench face, and the first horizontal trench and the second horizontal trench face.

In one embodiment, the electroluminescence display further includes a first emission layer disposed at the first pixel to the fourth pixel, disconnected by the first vertical trench, the second vertical trench, the first horizontal trench and the second horizontal trench, and connected to the induction electrode; a charge generation layer disposed on the first emission layer, disconnected by the first vertical trench, the second vertical trench, the first horizontal trench and the second horizontal trench, and connected passing over the induction electrode; and a second emission layer on the charge generation layer, and connected passing over the first vertical trench, the second vertical trench, the first horizontal trench, the second horizontal trench, and the induction electrode.

In one embodiment, the electroluminescence display further includes a plurality of first electrodes, each of the first electrode disposing at first pixel to fourth pixel; and a second electrode disposed on the second emission layer, and connected passing over the first vertical trench, the second vertical trench, the first horizontal trench, the second horizontal trench, and the induction electrode.

In one embodiment, the induction electrode is disposed at same layer and made of same material as the first electrode.

In one embodiment, the induction electrode is connected to an induction line disposed under the first vertical trench, the second vertical trench, the first horizontal trench and the second horizontal trench and over the substrate.

In one embodiment, the electroluminescence display further includes an intermediate electrode connecting the induction electrode to the induction line.

In one embodiment, the electroluminescence display further includes a cross trench at an intersection portion where the first vertical trench, the second vertical trench meet the first horizontal trench and the second horizontal trench. The induction electrode is disposed at a central area of the cross trench.

In addition, an electroluminescence display according to the present disclosure includes a substrate; a planarization layer on an entire surface of the substrate; a first electrode disposed on the planarization layer and including a first side, a second side perpendicular to the first side, and an intersection portion where the first side meets the second side; a trench disposed at an outside of the first side and the second side, and having a predetermined width; an induction electrode disposed at the intersection portion; a first emission layer disposed on the first electrode, disconnected by the trench, and connected to the induction electrode; a charge generation layer disposed on the first emission layer, disconnected by the trench, and connected through the induction electrode; a second emission layer disposed on the charge generation layer, connected passing over the trench, and connected passing over the induction electrode; and a second electrode disposed on the second emission layer, connected passing over the trench and the induction electrode.

In one embodiment, the charge generation layer is electrically disconnected from the cathode electrode.

In one embodiment, the first electrode further includes a third side parallel to the first side; and a fourth side parallel to the second side. The trench includes a first trench disposed outside the first side and the third side; and a second trench disposed outside the second side and the fourth side.

In one embodiment, the electroluminescence display further includes a first bank covering the first side, the second side, the third side and the fourth side of the first electrode, and exposing a central portion of the first pixel, and a second bank covering edge portions of the induction electrode and exposing a central portion of the induction electrode. The trench is formed by removing the bank and the planarization layer with a predetermined depth.

In one embodiment, the trench includes a first trench disposed outside the first side and corresponding to the first side; a second trench disposed outside the second side and corresponding to the second side; a third trench disposed outside the third side and corresponding to the third side; and a fourth trench disposed outside the fourth side and corresponding to the fourth side. The induction electrode has a rectangular shape including four sides corresponding the first to fourth trenches, respectively.

In one embodiment, the induction electrode is disposed at same layer and includes same material as the first electrode.

In one embodiment, the electroluminescence display further includes a cross trench surrounding the induction electrode and connected to the trench.

In one embodiment, the cross trench has a width narrower than a width of the trench.

In one embodiment, the first emission layer is disconnected by the cross trench. The charge generation layer is disconnected by the cross trench. The second emission layer is connected passing over the cross trench on the charge generation layer. The second electrode is disposed on the second emission layer and connected passing over the cross trench.

In one embodiment, the electroluminescence display further includes an induction line disposed under the planarization layer and on the substrate, and connected to the induction electrode.

In one embodiment, the electroluminescence display further includes an intermediate electrode connecting the induction electrode to the induction line.

The electroluminescent display according to the present disclosure includes a trench structure surrounding each pixel in the plan view. In particular, the electroluminescence display according to the present disclosure includes a vertical trench running in the Y-axis direction and a horizontal trench running in the X-axis direction. Therefore, the charge generation layer of the organic emission layer stacked on the entire surface of the substrate can have a structure in which electrical connectivity is disconnected (or cut off) in the horizontal direction (or X-axis direction) and the vertical direction (or Y-axis direction) in the plan view. As a result, image distortion due to the lateral leakage current between neighboring pixels can be prevented. In a network structure of the trenches, the width of the trench can be wider at the intersection portion than other portions. In the present disclosure, an induction electrode can be placed at the intersection portion of the trench to have a structure that discharges the lateral leakage current to the outside of the display device. Therefore, in a light emitting display device with an ultra-high-resolution structure, excellent image information can be provided by preventing the flow of the lateral leakage current in all directions or discharging it to the outside of the display device. Additionally, by preventing the lateral leakage current, power consumption can be reduced, so that it is possible to provide a low power driven light emitting display device (or electroluminescence display).

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plane view illustrating a schematic structure of an electroluminescence display according to an embodiment of the present disclosure.

FIG. 2 is a circuit diagram illustrating a structure of one pixel according to an embodiment of the present disclosure.

FIG. 3 is a plan view illustrating a structure of 2×2 pixels in the electroluminescence display according to an embodiment of the present disclosure.

FIG. 4 is a cross-sectional view along to cutting line I-I′ in FIG. 3, for illustrating the structure of a bottom emission type electroluminescence display according to an embodiment of the present disclosure.

FIG. 5 is an enlarged cross-sectional view illustrating a structure of part ‘A’ indicated by a dotted rectangle in FIG. 4 according to an embodiment of the present disclosure.

FIG. 6 is a cross-sectional view illustrating a structure of a top emission type electroluminescence display according to an embodiment of the present disclosure.

FIG. 7 is a plane view illustrating a structure of trench disposed between 2×2 pixels in an electroluminescence display according to an embodiment of the present disclosure.

FIG. 8 is a cross-sectional view along to cutting line II-II′ in FIG. 7, for illustrating a structure of an electroluminescence display according to an embodiment of the present disclosure.

FIG. 9 is a plane view illustrating a structure of 2×2 pixels in the electroluminescence display according to another embodiment of the present disclosure.

FIG. 10 is a cross-sectional view along to cutting line III-III′ in FIG. 9, for illustrating a structure of an electroluminescence display according to an embodiment of the present disclosure.

FIG. 11 is a plane view illustrating a structure of 2×2 pixels in the electroluminescence display according to another embodiment of the present disclosure.

FIG. 12 is a cross-sectional view, along to cutting line IV-IV' in FIG. 11, illustrating a structure of an electroluminescence display according to an embodiment of the present disclosure.

FIG. 13 is a plane view illustrating a structure of 2×2 pixels in the electroluminescence display according to another embodiment of the present disclosure.

FIG. 14 is a cross-sectional view, along to cutting line V-V′ in FIG. 11, illustrating a structure of an electroluminescence display according to an embodiment of the present disclosure.

### DETAILED DESCRIPTION OF THE EMBODIMENTS

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

Reference will now be made in detail to the example embodiments of the present disclosure, examples of which are illustrated in the accompanying drawings. Wherever possible. the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the situation that “comprise,” “have,” and “include” described in the present specification are used, another part can also be present unless “only” is used. The terms in a singular form can include plural forms unless noted to the contrary.

In construing an element, the element is construed as including an error range although there is no explicit description.

In describing a positional relationship, for example, when the positional order is described as “on,” “above,” “below,” and “next,” the situation of no contact there-between can be included, unless “just” or “direct” is used. If it is mentioned that a first element is positioned “on” a second element, it does not mean that the first element is essentially positioned above the second element in the figure. The upper part and the lower part of an object concerned can be changed depending on the orientation of the object. Consequently, the situation in which a first element is positioned “on” a second element includes the situation in which the first element is positioned “below” the second element as well as the situation in which the first clement is positioned “above” the second element in the figure or in an actual configuration.

In describing a temporal relationship, for example, when the temporal order is described as “after,” “subsequent,” “next,” and “before,” a situation which is not continuous can be included, unless “just” or “direct” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing the elements of the present disclosure, terms such as the first, the second, A. B. (a) and (b) can be used. These terms are only to distinguish the elements from other elements, and the terns are not limited in nature, order, sequence or number of the elements. When an clement is described as being “linked,” “coupled” or “connected” to another element that element can be directly connected to or connected to that other element, but indirectly unless otherwise specified. It is to be understood that other elements can be “interposed” between each element that can be connected to or coupled to.

It should be understood that the term “at least one” includes all combinations related with any one item. For example, “at least one among a first element, a second element and a third element” can include all combinations of two or more elements selected from the first, second and third elements as well as each element of the first, second and third elements.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Hereinafter, an example of a display apparatus according to the present disclosure will be described in detail with reference to the accompanying drawings. In designating reference numerals to elements of each drawing, the same components can have the same reference numerals as much as possible even though they are shown in different drawings. Scale of the elements shown in the accompanying drawings have a different scale from the actual for convenience of description, it is not limited to the scale shown in the drawings.

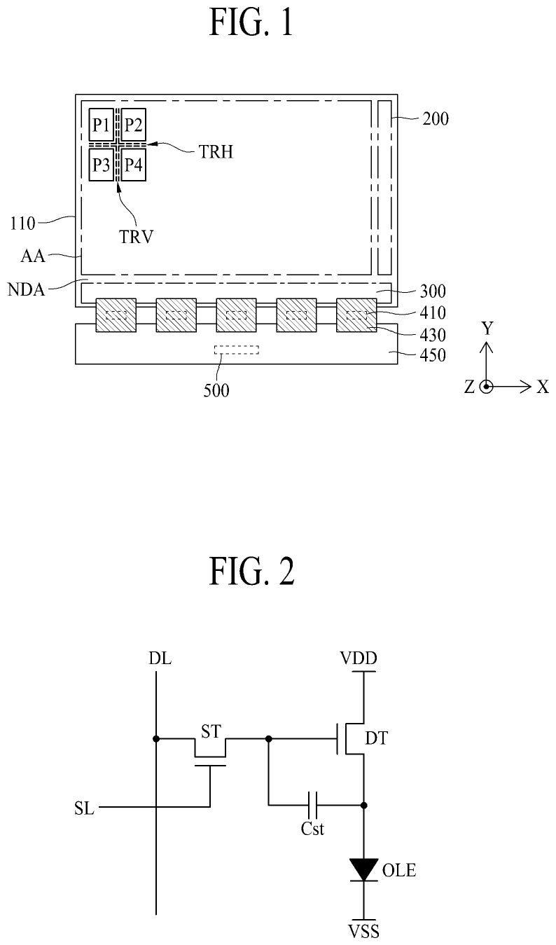

Hereinafter, referring to attached figures, various aspects of the present disclosure will be explained, in detail. FIG. 1 is a diagram illustrating a schematic structure of an electroluminescence display according to the present disclosure. In FIG. 1, the X-axis can be parallel to the extending direction of the scan line, the Y-axis can be parallel to the extending direction of the data line, and the Z-axis can represent the thickness direction of the display.

Referring to FIG. 1, the electroluminescence display includes a substrate 110, a gate (or scan) driver 200, a data pad portion 300, a source driving Integrated Circuit (IC) 410, a flexible circuit film 430, a circuit board 450, and a timing controller 500.

The substrate 110 can include an electrical insulating material or a flexible material. The substrate 110 can be made of a glass, a metal or a plastic, but it is not limited thereto. When the electroluminescence display is a flexible display, the substrate 110 can be made of the flexible material such as plastic. For example, the substrate 110 can include a transparent polyimide material.

The substrate 110 can include a display area DA and a non-display area NDA. The display area DA, which is an area for representing the video images, can be defined as the majority middle area of the substrate 110, but it is not limited thereto. In the display arca DA, a plurality of scan lines (or gate lines), a plurality of data lines and a plurality of pixels P1, P2, P3 and P4 can be formed or disposed.

Here, the pixel P can represent any one of red, green and blue or any one of red, green, blue and white. A red pixel, a green pixel and a blue pixel can be grouped together, or a red pixel, a green pixel, a blue pixel and a white pixel can be gathered together to form one unit pixel. For an example, each pixel representing each color can be named a ‘sub-pixel’ and it can be explained that these ‘sub-pixels’ form one ‘pixel.’ For another example, the pixels representing each color can be named ‘pixels P’ and it can be explained that three or four of these ‘pixels P’ are gathered to form one ‘unit pixel.’ Hereinafter, the later situation will be used for explaining the present disclosure.

The non-display area NDA, which is an area not representing the video images, can be defined at the circumference areas of the substrate 110 surrounding all or some of the display area DA. In the non-display area NDA, the gate driver 200 and the data pad portion 300 can be formed or disposed.

The gate driver 200 can supply the scan (or gate) signals to the scan lines according to the gate control signal received from the timing controller 500. The gate driver 200 can be formed at the non-display area NDA at any one outside of the display area DA on the substrate 110, as a Gate driver In Panel (GIP) type. GIP type means that the gate driver 210 is directly formed on the substrate 110.

The data pad portion 300 can supply the data signals to the data line according to the data control signal received from the timing controller 500. The data pad portion 300 can be made as a driver chip and mounted on the flexible circuit film 430. Further, the flexible circuit film 430 can be attached at the non-display area NDA at any one outside of the display area DA on the substrate 110, as a Tape Automated Bonding (TAB) type.

The source driving IC 410 can receive the digital video data and the source control signal from the timing controller 500. The source driving IC 410 can convert the digital video data into the analog data voltages according to the source control signal and then supply that to the data lines. When the source driving IC 410 is made as a chip type, it can be installed on the flexible circuit film 430 as a Chip On Film (COF) or Chip On Plastic (COP) type.

The flexible circuit film 430 can include a plurality of first link lines connecting the data pad portion 300 to the source driving IC 410, and a plurality of second link lines connecting the data pad portion 300 to the circuit board 450. The flexible circuit film 430 can be attached on the data pad portion 300 using an anisotropic conducting film, so that the data pad portion 310 can be connected to the first link lines of the flexible circuit film 430.

The circuit board 450 can be attached to the flexible circuit film 430. The circuit board 450 can include a plurality of circuits implemented as the driving chips. For example, the circuit board 450 can be a printed circuit board or a flexible printed circuit board.

The timing controller 500 can receive the digital video data and the timing signal from an external system board through the line cables of the circuit board 450. The timing controller 500 can generate a gate control signal for controlling the operation timing of the gate driver 200 and a source control signal for controlling the source driving IC 410, based on the timing signal. The timing controller 500 can supply the gate control signal to the gate driver 200 and supply the source control signal to the source driving IC 410. Depending on the product types, the timing controller 500 can be formed as one chip with the source driving IC 410 and mounted on the substrate 110.

### First Embodiment

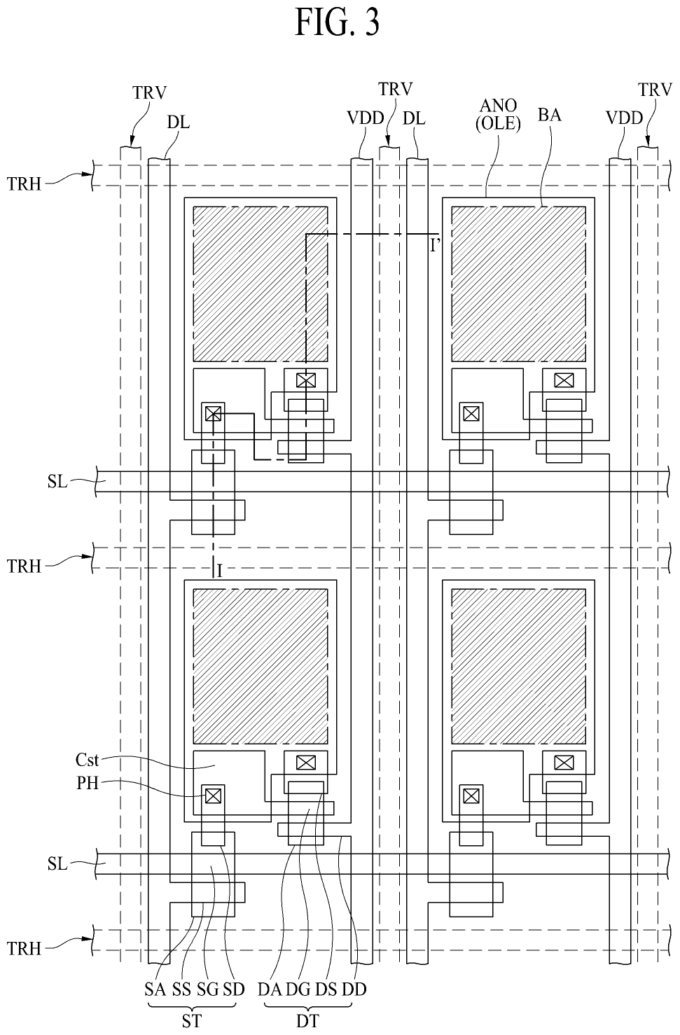

Hereinafter, referring to FIGS. 2 to 7, an electroluminescence display according to a first embodiment of the present disclosure will be explained. FIG. 2 is a circuit diagram illustrating a structure of one pixel according to an example embodiment of the present disclosure. FIG. 3 is a plan view illustrating a structure of 2×2 pixels in the electroluminescence display according to the first embodiment of the present disclosure.

Referring to FIGS. 2 to 3, one-pixel P of the light emitting display can be defined by a scan line SL, a data line DL and a driving current line VDD. One pixel of the light emitting display can include a switching thin film transistor ST, a driving thin film transistor DT, a light emitting diode OLE and a storage capacitance Cst. The driving current line VDD can be supplied with a high-level voltage for driving the light emitting diode OLE.

For example, the switching thin film transistor ST can be disposed at the portion where the scan line SL and the data line DL is crossing. The switching thin film transistor ST can include a gate electrode SG, a semiconductor layer SA, a source electrode SS and a drain electrode SD. The gate electrode SG can be a portion of the scan line SL. The semiconductor layer SA is disposed as crossing over the gate electrode SG. The portion of semiconductor layer SA overlapped with the gate electrode SG is defined as a channel region. The source electrode SS can be connected to or branched from the data line DL and the drain electrode SD can be connected to the driving thin film transistor DT. By supplying the data signal to the driving thin film transistor DT, the switching thin film transistor ST can play a role of selecting a pixel which would be driven.

The driving thin film transistor DT can play a role of driving the light emitting diode OLE of the selected pixel by the switching thin film transistor ST. The driving thin film transistor DT can include a gate electrode DG, a semiconductor layer DA, a source electrode DS and a drain electrode DD. The gate electrode DG of the driving thin film transistor DT can be connected to the drain electrode SD of the switching thin film transistor ST. For example, the gate electrode DG of the driving thin film transistor DT can be extended from the drain electrode SD of the switching thin film transistor ST. The drain electrode DD can be connected to or branched from the driving current line VDD, and the source electrode DS can be connected to an anode electrode ANO of the light emitting diode or light emitting element (OLE). A storage capacitance Cst can be disposed between the gate electrode DG of the driving thin film transistor DT and the anode electrode ANO of the light emitting diode OLE.

The driving thin film transistor DT can be disposed between the driving current line VDD and the light emitting diode OLE. The driving thin film transistor DT can control the amount of electric current flowing to the light emitting diode OLE from the driving current line VDD according to the voltage level difference between the gate electrode DG and the source electrode DS.

The light emitting diode OLE can include an anode electrode ANO, an emission layer EL and a cathode electrode CAT. The light emitting diode OLE emits light according to electric current controlled by the driving thin film transistor DT. The light emitting diode OLE can display an image by emitting light according to the electric current controlled by the driving thin film transistor DT. The anode electrode ANO of the light emitting diode OLE is connected to the source electrode DS of the driving thin film transistor DT, and the cathode electrode CAT is connected to the low-power line VSS to which a low potential voltage is supplied. The light emitting diode OLE is driven by the current flowing from the driving current line VDD to the low-power line VSS by the driving thin film transistor DT.

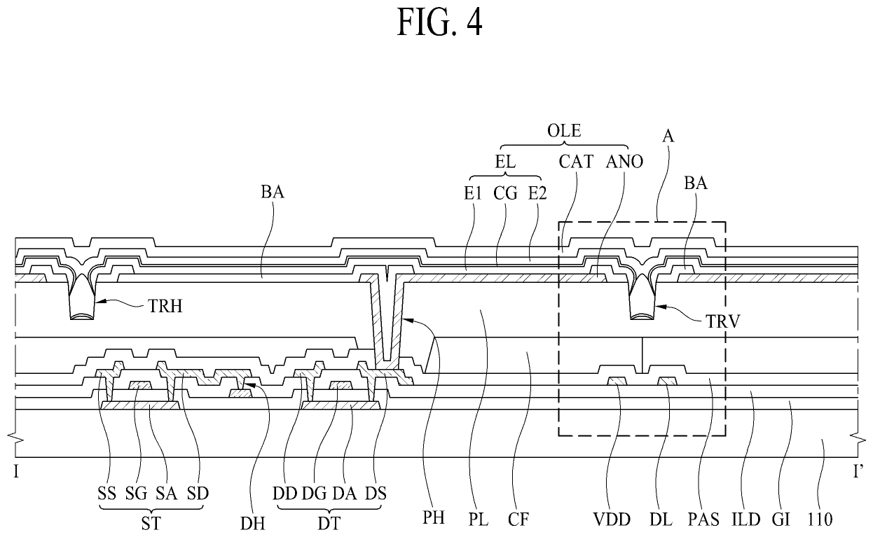

With further reference to FIG. 4, the cross-sectional structure of the light emitting display device according to the present disclosure will be described. FIG. 4 is a cross-sectional view along to cutting line I-I′ in FIG. 3, for illustrating the structure of a bottom emission type electroluminescence display according to the first embodiment of the present disclosure.

A semiconductor layer SA of the switching thin film transistor ST and a semiconductor layer DA of the driving thin film transistor DT are formed on the substrate 110. Also, a buffer layer can be further disposed between the semiconductor layers SA and DA and the substrate 110.

A gate insulating layer GI is deposited on the semiconductor layers SA and DA and the substrate 110. A gate electrode SG of the switching thin film transistor ST and a gate electrode DG of the driving thin film transistor DT are formed on the gate insulating layer GI. The gate electrode SG of the switching thin film transistor ST is disposed as overlapping with a portion of the semiconductor layer SA of the switching thin film transistor ST. In the switching thin film transistor ST, the area of the semiconductor layer SA that overlaps with the gate electrode SG is defined as a channel area. Likewise, the gate electrode DG of the driving thin film transistor DT is disposed to overlap with a portion of the semiconductor layer DA of the driving thin film transistor DT. The area of the semiconductor layer DA that overlaps with the gate electrode DG in the driving thin film transistor DT is defined as a channel arca.

An intermediate insulating layer ILD is deposited on the gate electrodes SG and DG and the gate insulating layer GI. A source and drain electrodes SS, SD, DS and DD are formed on the intermediate insulating layer ILD. In detail, the source electrode SS of the switching thin film transistor ST is formed that contacts one side of the semiconductor layer SA of the switching thin film transistor ST, and the drain electrode SD of the switching thin film transistor ST is formed that contacts the other side. The source electrode DS of the driving thin film transistor DT is formed that contacts one side of the semiconductor layer DA of the driving thin film transistor DT, and a drain electrode DD of the driving thin film transistor DT is formed that contacts the other side of the semiconductor layer DA.

The source electrode SS of the switching thin film transistor ST is branched from the data line DL. The drain electrode DD of the driving thin film transistor DT is branched from the driving current line VDD. In addition, the drain electrode SD of the switching thin film transistor ST is connected to the gate electrode DG of the driving thin film transistor DT through the drain contact hole DH formed in the intermediate insulating layer ILD.

The passivation layer PAS can be deposited on the top surface of the substrate 110 having the thin film transistors ST and DT. It is preferable that the passivation layer PAS is made of inorganic material, such as silicon oxide (SiOx) or silicon nitride (SiNx). The color filter CF can be formed on the passivation layer PAS. It is preferable that the color filter CF can be disposed as fully overlapping with the anode electrode ANO which can be formed later.

The planarization layer PL can be deposited on the passivation layer PAS and the color filter CF. The planarization layer PL can be the film layer for flattening the non-uniform surface of the substrate 110 on which the thin film transistors ST and DT are formed. In order to make the even surface condition of the substrate 110, the planarization layer PL can be formed of an organic material. The passivation layer PAS and the planarization layer PL can include the pixel contact hole PH exposing some portions of the source electrode DS of the driving thin film transistor DT.

The anode electrode ANO can be formed on the planarization layer PL. The anode electrode ANO can be connected to the drain electrode DD of the driving thin film transistor DT through a pixel contact hole PH formed at the planarization layer PL. The anode electrode ANO can have various structures and different materials according to the emission type of the organic light emitting diode OLE. For an example, for the bottom emission type in which the light can be provided to the substrate 110 direction from the emission layer EL, the anode electrode ANO can be made of a transparent conductive material. For example, the anode electrode ANO of the bottom emission type can include oxide conductive material, such as indium-zinc-oxide (or IZO) or indium-tin-oxide (or ITO). For another example, for the top emission type in which the light can be provided to the upper direction opposite the substrate 110, the anode electrode ANO can be made of metal materials having excellent light reflectance. FIG. 4 shows the structure of the bottom emission type.

A bank BA can be formed on the anode electrode ANO. The bank BA can cover the circumference areas of the anode electrode ANO and can expose most of the middle area of the anode electrode ANO. The middle area of the anode electrode ANO exposed by the bank BA can be defined an emission area.

The trench TR can be disposed between the pixels formed by removing some portions of the bank BA and the planarization layer PL. The trench TR can include a horizontal trench TRH and a vertical trench TRV. The horizontal trench TRH can extend along the X-axis direction or transverse direction in a plane view on the substrate 110. The vertical trench TRV can extend along the Y-axis direction or longitudinal direction in a plane view on the substrate 110. One vertical trench TRV can be disposed at the left side and the right side of the pixel, and one horizontal trench TRH can be disposed at the upper side and the lower side of the pixel. For example, the vertical trench TRV can be disposed between the driving current line VDD and data line DL, and the horizontal trench TRH can be disposed parallel to a scan line SL, but embodiments are not limited thereto.

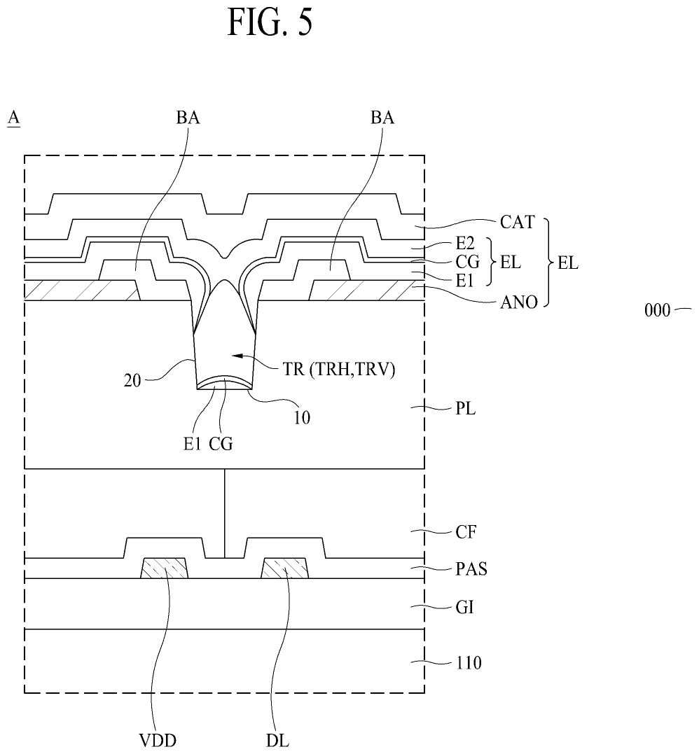

Hereinafter, referring to FIG. 5, detailed structures of the trenches TRV, TRH will be explained. FIG. 5 is an enlarged cross-sectional view illustrating a structure of part ‘A’ indicated by a dotted rectangle in FIG. 4 according to an embodiment. FIG. 5 is an enlarged view of the vertical trench TRV, but the horizontal trench TRH can also have the same structure, but embodiments are not limited thereto. For example, the vertical trench TRV and the horizontal trench TRH can have different structures.

An emission layer EL can be deposited on the bank BA and the anode electrode ANO. The emission layer EL can be deposited over the whole surface of the display area DA on the substrate 110, as covering the anode electrodes ANO and banks BA. For an example, the emission layer EL can include two or more stacked emission portions for emitting white light. In detail, the emission layer EL can include a first emission layer providing first color light and a second emission layer providing second color light, for emitting the white light by combining the first color light and the second color light. In this situation, a charge generation layer CG can be disposed between the first emission layer E1 and the second emission layer E2. The first emission layer E1, which is disposed between the anode electrode ANO and the charge generation layer CG, can emit the first color light. The second emission layer E2, which is disposed between the charge generation layer CG and the cathode electrode CAT, can emit the second color light.

The cathode electrode CAT can be disposed on the emission layer EL. The cathode electrode CAT can be stacked on the emission layer EL as being in surface contact with the second emission layer E2. The cathode electrode CAT can be formed as one sheet element over the whole area of the substrate 110 as being commonly connected whole emission layers EL disposed at all pixels. In the situation of the bottom emission type, the cathode electrode CAT can include metal material having excellent light reflection ratio. For example, the cathode electrode CAT can include at least any one of silver (Ag), aluminum (Al), molybdenum (Mo), gold (Au), magnesium (Mg), calcium (Ca), or barium (Ba).

Hereinafter, referring to FIG. 5, the structure for cutting, pinching or disconnecting the electric connection between the pixels by the trench will be described. FIG. 5 is an enlarged cross-sectional view illustrating a structure of part ‘A’ indicated by a dotted rectangle in FIG. 4.

The gate insulating layer GI is deposited on the substrate 110. The driving current line VDD and the data line DL are formed on the gate insulating layer GI. The passivation layer PAS is deposited on the driving current line VDD and the data line DL. The color filter CF is deposited on the passivation layer PAS. For example, between any neighboring two pixels, a red color filter can be formed at the left pixel and a green color filter can be formed at the right pixel.

The planarization layer PL is deposited on the color filter CF. The anode electrode ANO is formed on the planarization layer PL. The bank BA is formed on the anode electrode ANO as covering circumference areas of the anode electrode ANO. Between two neighboring pixels, the trench TR is disposed. The trench TR can be formed by etching some portions of the bank BA and the planarization layer PL with a predetermined depth. For example, the trench TR (TRH, TRV) can extend all the way through the bank BA and only can only extend partially into the planarization layer PL (e.g., the trench TR can extend halfway through the planarization layer PL), but embodiments are not limited thereto. According to another embodiment, the trench TR (TRH, TRV) can also extend all the way through the planarization layer PL. The etched portions can be disposed between two neighboring anode electrodes ANO. FIG. 5 illustrates, for convenience, only the structure of the vertical trench TRV disposed between the driving current line VDD and the data line DL, the horizontal trench TRH can also have the same structure. Also, as shown in FIG. 3, the TR (TRH, TRV) can fully surround each of the subpixels in the plan view.

The trench TR can include a well structure having a bottom surface 10 and the side-wall surface 20. Within the trench TR, the first emission layer E1 is deposited on the anode electrode ANO and the bank BA. As the result, the first emission layer E1 can be deposited on the bottom surface 10 of the trench TR. However, on the side-wall surface 20, the first emission layer E1 may not be fully deposited, but it can be partially deposited at the top portions of the trench TR. That is, the first emission layer E1 can be deposited on the surface of the substrate 110, but the electrical connection of the first emission layer E1 can be cut or disconnected, so that the first emission layer E1 can be separated in pixel unit.

The charge generation layer CG is deposited on the first emission layer E1. On the bottom surface 10 of the trench TR, the charge generation layer CG can be deposited on the first emission layer E1. On the side-wall surface 20, the charge generation layer CG can be partially deposited at the top portions. For example, the stacked shape of the charge generation layer CG can have a shape as covering some portions of the first emission layer E1. In some situations, the charge generation layer CG can cover the whole of the first emission layer E1. The charge generation layer CG can be deposited on the surface of the substrate 110, but the electrical connection of the charge generation layer CG can be cut or disconnected, so that the charge generation layer CG can be separated in pixel unit.

The second emission layer E2 is deposited on the charge generation layer CG. The top portions of the trench TR is in a state in which a width of the trench TR is narrowed due to the previously stacked profile of the first emission layer E1 and the charge generation layer CG. Under this condition, as the deposition process of the second emission layer E2 is performed, the second emission layer E2 thickened from the left side and the second emission layer E2 thickened from the right side can contact each other at the top portion of the trench TR. Thus, a cross sectional shape (or profile) of the top space of the trench TR can be filled or closed. As the result, the second emission layer E2 can have a structure in which the second emission layer E2 can be connected over all pixels on the whole surface of the substrate 110. Further, the second emission layer E2 may not be deposited within the trench TR. However, according to the depth or the height of the trench TR, some portions of the second emission layer E2 can be disconnected by the trench TR. For example, the second emission layer E2 can bridge or extend across the trench TR. Also, a void of empty space can be created within the trench TR in a space between a portion of the charge generation layer CG and a portion of the second emission layer E2.

After that, the cathode electrode CAT is deposited on the second emission layer E2. Since the second emission layer E2 has a structure connected between all pixels on the entire surface of the substate 110, the cathode electrode CAT also has a structure connected between all pixels. For example, the cathode electrode CAT can extend across the trench TR. Also, an encapsulation layer can be deposited on the cathode electrode CAT.

With the structure as shown in FIG. 5, the first emission layer E1 deposited just on the anode electrode ANO can include a hole transport layer. Since the first emission layer E1 is divided for each pixel by the trench TR, a problem in which charges move between neighboring pixels through the charge transport layer can be prevented. In addition, since the charge generation layer CG stacked on the first emission layer E1 is also divided in pixel units by the trench TR, the problem in which charges move between neighboring pixels by through the charge generation layer CG can be prevented.

The second emission layer E2 can include an electron transport layer. It is preferable that the electron transport layer is a common layer connected over all pixels, like the cathode electrode CAT. Even though the electrons can move between neighboring pixels through the electron transport layer, the flow of the holes can be blocked between neighboring pixels due to the trench TR. Therefore, there is no problem of the display quality due to the lateral leakage current.

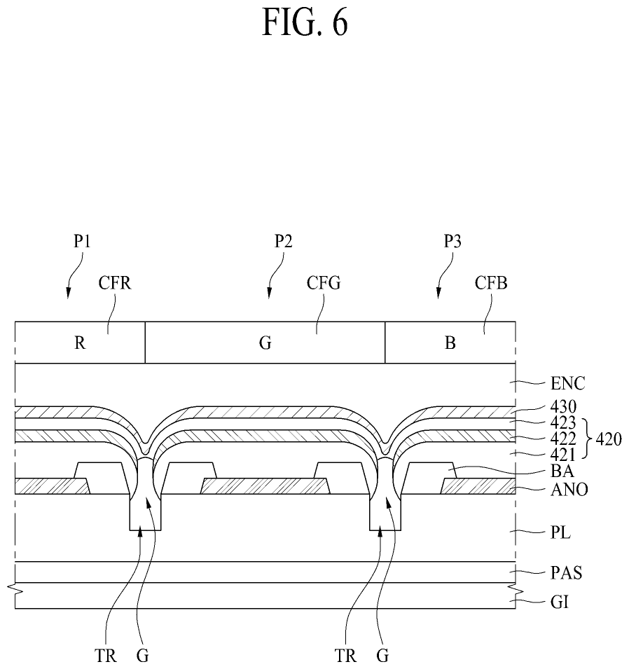

With FIGS. 4 and 5, the bottom emission type electroluminescence display having the structure for suppressing the lateral leakage current by the trench according to the first embodiment was explained. The features of the present disclosure can be applied to the top emission type electroluminescence display as shown in FIG. 6. FIG. 6 is a cross-sectional view illustrating a structure of an electroluminescence display according to the first embodiment of the present disclosure.

Referring to FIG. 6, the electroluminescence display according to another example of the first embodiment can include a substrate, a circuit element layer, a passivation layer PAS, a planarization layer PL, a first electrode ANO, an emission layer EL, a second electrode CAT, a bank BA, an encapsulation layer ENC, a first color filter CFR, a second color filter CFG and a third color filter CFB. The substrate and circuit element layer can be the same with substrate 110 and thin film transistors ST and DT explained above, so the explanation for these elements may not be repeated.

The electroluminescence display shown in FIG. 6 can have a top emission structure in which the light from the emission layer can be emitted to the upward direction opposite the substrate. Therefore, the substrate can be made of transparent material or an opaque material.

The planarization layer PL can be deposited on the circuit element layer. The planarization layer PL can be made of an organic material, such as acryl resin, epoxy resin, phenolic resin, polyamide resin and polyimide resin. Otherwise, the planarization layer PL can be made of an inorganic material, such as silicon nitride, aluminum nitride, zirconium nitride, titanium nitride, hafnium nitride, tantalum nitride, silicon oxide, aluminum oxide or titanium oxide.

The planarization layer PL can have the trench TR disposed at the border area between the first pixel P1 and the second pixel P2 and at the border area between the second pixel P2 and the third pixel P3. The trench TR can be disposed at an area between the bank BA covering the end of the first electrode ANO of the first pixel P1 and the bank BA covering the end of the first electrode ANO of the second pixel P2, and at an area between the bank BA covering the end of the first electrode ANO of the second pixel P2 and the bank BA covering the end of the first electrode ANO of the third pixel P3. The trench TR can be dug or extend into a predetermined region inside the planarization layer PL without penetrating all the way through the planarization layer PL. However, it is not limited thereto. The trench TR can pass all the way through the planarization layer PL and can extend into a predetermined region inside the circuit element layer below the planarization layer PL.

The bank BA can be formed at the boundary area between the adjacent pixels P1 to P3 in a matrix structure. One end of the bank BA can be disposed to be in contact with the entrance (or upper aperture) of the trench TR, or can be spaced apart from the entrance of the trench TR by a predetermined distance. The bank BA can be formed as covering both end portions of the first anode electrode disposed at the first to third pixels P1 to P3. Therefore, the exposed portion of the first electrode ANO not covered by the bank BA can be defined as the emission area.

The emission layer 420 can be formed on the bank BA and the first electrode ANO. That is, the emission layer 420 can be formed as covering the boundary areas of the adjacent pixels P1 to P3. The emission layer 420 can be configured to emit white light. In this situation, the emission layer 420 can include a plurality of stacks that emit light of different colors. For example, the emission layer 420 can include a first stack 421, a second stack 423 and a charge generation layer (or CGL) 422 provided between the first stack 421 and the second stack 423.

For example, the first stack 421 can include a hole injection layer, a first hole transport layer, a first organic emission layer and a first electron transport layer sequentially stacked. The second stack 423 can include a second hole transport layer, a second organic emission layer, a second electron transport layer and an electron injection layer sequentially stacked. The charge generation layer 422 can include a N-type charge generation layer supplying electrons to the first stack 421 and a P-type charge generation layer supplying holes to the second stack 423.

The emission layer 420 can be formed inside the trench TR and on the trench TR. When the emission layer 420 is disposed inside the trench TR, the emission layer 420 can be disconnected, pinched or cut between the neighboring two pixels, so the leakage current between the adjacent pixels P1 to P3 can be prevented or minimized.

In detail, the first stack 421 can be disposed inside wall and bottom surface of the trench TR. Here, the first stack 421 can be completely disconnected without being continuous over the trench TR. Therefore, the electric carriers do not flow through the first stack 421 between the first pixel P1 and the second pixel P2 and between the second pixel P2 and the third pixel P3 which are adjacent each other with the trench TR interposed there-between.

The charge generation layer 422 can be deposited on the first stack 421. Here, the charge generation layer 422 can be completely disconnected at the inside of the trench TR or a region overlapping the trench TR. Therefore, the electric carriers do not flow through the charge generation layer 422 between the first pixel P1 and the second pixel P2 and between the second pixel P2 and the third pixel P3 which are adjacent each other with the trench TR interposed there-between.

The second stack 423 can be deposited on the charge generation layer 422. Here. the second stack 423 can be continuously disposed between the first pixel P1 and the second pixel P2 and between the second pixel P2 and the third pixel P3 which are adjacent each other with the trench TR interposed there-between. Also, the second stack 423 can be pinched or have a thinner thickness in the area over the trench TR. In some situations, the second stack 423 can be disconnected at some portions by the trench TR but can be connected at other portions over the trench TR. Therefore, the electric carriers may be flow through the second stack 423 between the first pixel P1 and the second pixel P2 and between the second pixel P2 and the third pixel P3 which are adjacent each other with the trench TR interposed there-between.

Due to the above-mentioned structures of the first stack 421, the charge generation layer 422 and the second stack 423, an empty gap (or void) G can be provided in the emission layer 420. In detail, the void G can be formed inside the trench TR and can extend over the trench TR. Here, the upper end of the void G can be located at a higher position than the charge generating layer 422, so that the charge generation layer 422 can be disconnected by the void G at the trench TR. In addition, the width of the void G can be gradually narrowed from the bottom of the void G to the top of the void G. For example, the void G can have a tapered shape relative to the substrate.

The second electrode 430 can be formed on the second stack 423. The second electrode 430 can be the cathode electrode of the display. The second electrode 430 can be deposited over the pixels P1 to P3 and the boundary areas between the pixels P1 to P3. Since the upper surface of the second stack 423 is not disconnected, the second electrode 430 can be deposited on the emission layer 420 in stable, the profile of the second electrode 430 can have concaved shape at the area overlapping the trench TR.

Since the display shown in FIG. 6 can have the top emission type, the second electrode CAT can be made of a transparent conductive material, such as indium-tin-oxide (ITO) or indium-zinc-oxide (IZO), in order to transmit the light emitted from the emission layer EL toward the upper direction. In addition, the second electrode 430 can be made of a semi-transmissive metallic material, such as magnesium (Mg), silver (Ag), or magnesium-silver alloy (Mg—Ag).

The encapsulation layer ENC can be disposed on the second electrode 430. The encapsulation layer ENC can be made of an inorganic material, an organic material or a mixture of an inorganic material and an organic material, and can be configured as a single layer or a multi-layer. The color filters can be disposed on the encapsulation layer ENC. The color filters can include a first color filter CFR representing red color R allocated at the first pixel P1, a second color filter CFG representing green color G allocated at the second pixel P2, and a third color filter CFB representing blue color B allocated at the third pixel P3. For the first pixel P1. only the red color R can be transmitted as the white color light passes through the first color filter CFR. For the second pixel P2, only the green color G can be transmitted as the white color light passes through the second color filter CFG. For the third pixel P3, only the blue color B can be transmitted as the white color light passes through the third color filter CFB.

Accordingly, in the first embodiment, by disconnecting the charge generation layer 422 at the boundary areas between the pixels P1 to P3 using the trench TR disposed under the emission layer 420, lateral leakage current flowing between the boundary areas of adjacent pixels P1 to P3 can be blocked or prevented. In detail, the charge generation layer 422 can have higher conductivity than the first stack 421 and the second stack 423. Specifically, since the N-type charge generation layer of the charge generation layer 422 can include metal material, it has higher conductivity than the first stack 421 and the second stack 423. The electrical carriers can mainly flow through the charge generation layer 422 between the pixels P1 to P3, so the amount of electrical carriers through the second stack 423 can be very low. Therefore, by forming the charge generation layer 422 to be disconnected or cut at the inside of the trench TR, it is possible to reduce the movement of the electrical carriers between the pixels P1 to P3 disposed adjacent to each other, so that the occurrence of the lateral leakage current can be prevented or minimized.

In the above first embodiment, an electroluminescence display having a structure for preventing the lateral leakage current by forming a trench TR surrounding cach pixel has been described. As the density of the pixels increases, the size of the pixels dependently decreases, and the distance between the pixels decreases (e.g., subpixels/pixels become packed more closely together). In the situation of the pixel density not being high, for example, 1K PPI (Pixel Per Inch) or less, the lateral leakage current between neighboring pixels along the X-axis direction that is turned on at the same time according to the scan signal can be the main cause of image quality degradation. Accordingly, only with the vertical trench TRV extending along the Y-axis direction between the pixels can sufficiently prevent deterioration of image quality due to the lateral leakage current. However, when the pixel density is increased, for example, 1K to 2K PPI, the lateral leakage current between pixels adjacent along the Y-axis direction can cause image quality degradation. As a result, it is desirable to have a structure in which a horizontal trench TRH extending along the X-axis direction is further added, so that image quality deterioration due to the lateral leakage current can be completely prevented, as explained in the first embodiment. In other words, cach pixel/subpixel can be completely surrounded by the trench TR in the plan view.

Furthermore, when the pixel density is much higher, for example, in the situation of ultra-high resolution of 4K PPI or higher, the distance between pixels becomes very narrow, and the width of the trench must be narrowed also. Under this condition, a problem occurs in that the width of the trench is widened at a portion where the horizontal trench TRH and the vertical trench TRV intersect.

It is preferable that the width of the trench TR is determined in consideration of the thickness of the first emission layer E1, the charge generation layer CG and the second emission layer E2 stacked on the anode electrode ANO, so that the first emission layer E1 and the charge generation layer CG are disconnected by the trench TR. In this situation, the width of the trench TR can be widened where the horizontal trench TRH and the vertical trench TRV intersect with each other. As a result, the charge generation layer CG can be contacted with the cathode electrode CAT, so that the light emitting diode can be defected.

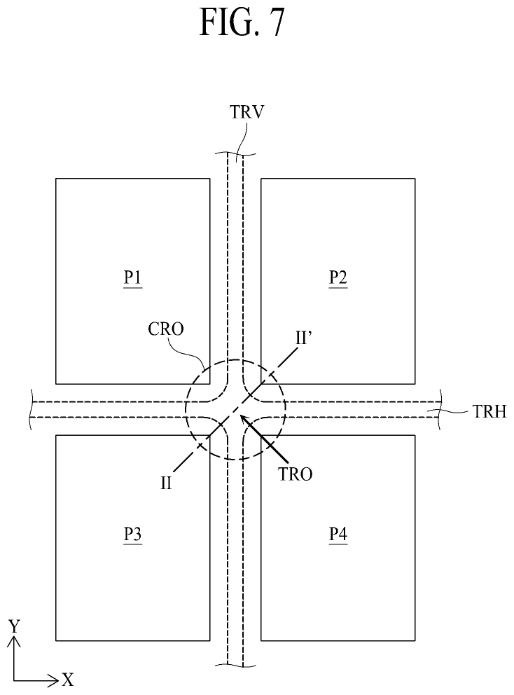

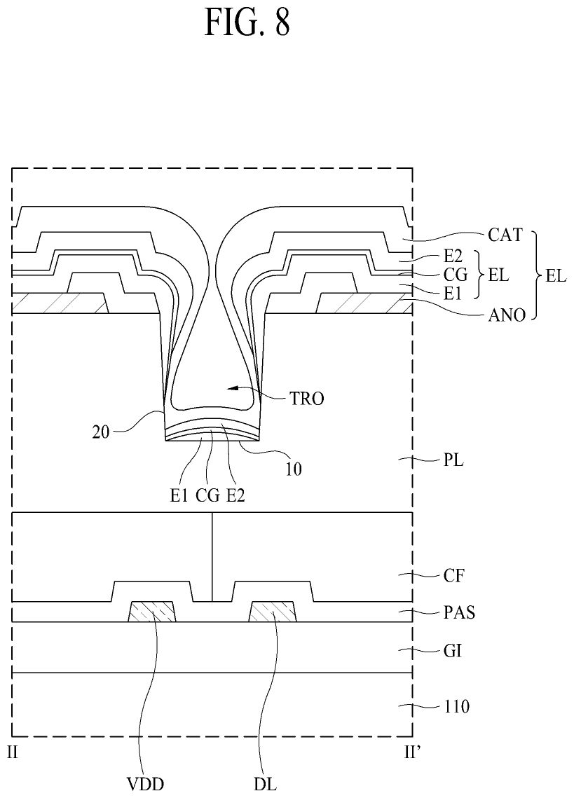

This will be explained in detail with reference to FIGS. 7 and 8. FIG. 7 is a plane view illustrating a structure of trench disposed between 2×2 pixels in an electroluminescence display according to the first embodiment of the present disclosure. FIG. 8 is a cross-sectional view along to cutting line II-II′ in FIG. 7, for illustrating a structure of an electroluminescence display according to the first embodiment of the present disclosure.

As shown in FIG. 7, a description will be made based on a 2×2 matrix structure. The first pixel P1 can be arranged in 1^{st} row and 1^{st} column, the second pixel P2 can be arranged in 1^{st} row and 2^{nd} column, the third pixel P3 can be arranged in 2^{nd} row and 1^{st} column, and the fourth pixel P4 can be arranged in 2^{nd} row and 2^{nd} column. The vertical trench TRV can be disposed between the first pixel P1 and the second pixel P2 and between the third pixel P3 and the fourth pixel P4. The horizontal trench TRH can be disposed between the first pixel P1 and the third pixel P3 and between the second pixel P2 and the fourth pixel P4.

The vertical trench TRV and the horizontal trench TRH can have a predetermined width. In this situation, the etchant can be concentrated at the intersection portion CRO where the vertical trench TRV and the horizontal trench TRH cross with each other or meet, so that the corner portions are over etched (e.g., double etched) and a cross-trench TRO can be formed with a wider width than the vertical trench TRV and the horizontal trench TRH.

With the condition in which the cross-trench TRO having a width wider than those of the vertical trench TRV and the horizontal trench TRH, the first emission layer E1 can be deposited on the anode electrode ANO and the bank BA. As the result, even though the first emission layer E1 can be stacked on the bottom surface 10 of the cross-trench TRO, it is not stacked on the side wall surface 20 and is stacked on the top surface. The first emission layer E1 can be deposited on the whole surface of the substrate 110, but the connectivity of the first emission layer E1 can be disconnected or completely cut by the cross-trench TRO, so that the first emission layer E1 can be separated in pixels.

The charge generation layer CG can be deposited on the first emission layer E1. On the bottom surface 10 of the cross-trench TRO, the charge generation layer CG can be stacked on the first emission layer E1. On the side wall surface 20, the charge generation layer CG can cover the first emission layer E1 and can extend to the bottom of the side wall surface 20. This can be caused because the width of the cross-trench TRO is wider than those of the other trenches TRV and TRH. The charge generation layer CG can be deposited on the whole surface of the substrate 110, but the connectivity of the charge generation layer CG can be disconnected or cut by the cross-trench TRO, so that the charge generation layer CG can be separated in pixels.

The second emission layer E2 is deposited on the charge generation layer CG. On the bottom surface 10 of the cross-trench TRO, the second emission layer E2 can be stacked on the charge generation layer CG. As the deposition process of the second emission layer E2 is performed, the second emission layer E2 thickened from the left pixel and the second emission layer E2 thickened from the right pixel can cover the charge generation layer CG at the upper portion of the trench TR. However, the upper portion of the cross-trench TRO may not be closed and can be formed in an open structure. For example, the cross-trench TRO may not include any void and can be completely filled with the various layers, but embodiments are not limited thereto.

In addition, the cathode electrode CAT can be deposited on the second emission layer E2. Since the cross-trench TRO is not closed or covered by the second emission layer E2, the cathode electrode CAT can be deposited along the open shaped profile of the cross-trench TRO so as to be deposited on the side wall surface 20 and the bottom surface 10. That is, the cathode electrode CAT can have a deposited profile connecting all pixels via the side-wall surface 20 and the bottom surface 10 of the cross-trench TRO. For example, the cathode electrode CAT can be the only layer that extends continuously across the cross-trench TRO, but embodiments are not limited thereto.

Under this structure, the cathode electrode CAT can directly contact the exposed charge generation layer CG on the side wall 20 of the cross-trench TRO. When the cathode electrode CAT and the charge generation layer CG are directly connected in this way, the normal structure of the light emitting diode EL by the stacked structure of the anode electrode ANO, the organic emission layer EL and the cathode electrode CAT is not formed. Therefore, the light emitting diode EL can be defective.

In addition, the cathode electrode CAT can be deposited too thin on the side wall 20 of the cross-trench TRO or the connectivity of the cathode electrode CAT over the entire surface of the substrate 110 can be disconnected. In this situation, the cathode electrode CAT can be disconnected between neighboring pixels, and a low-potential voltage may not be applied evenly to the entire cathode electrode CAT.

### Second Embodiment

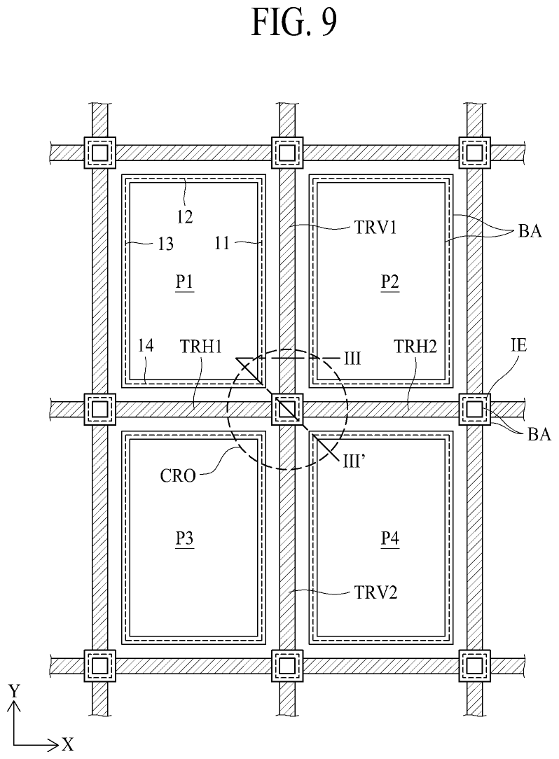

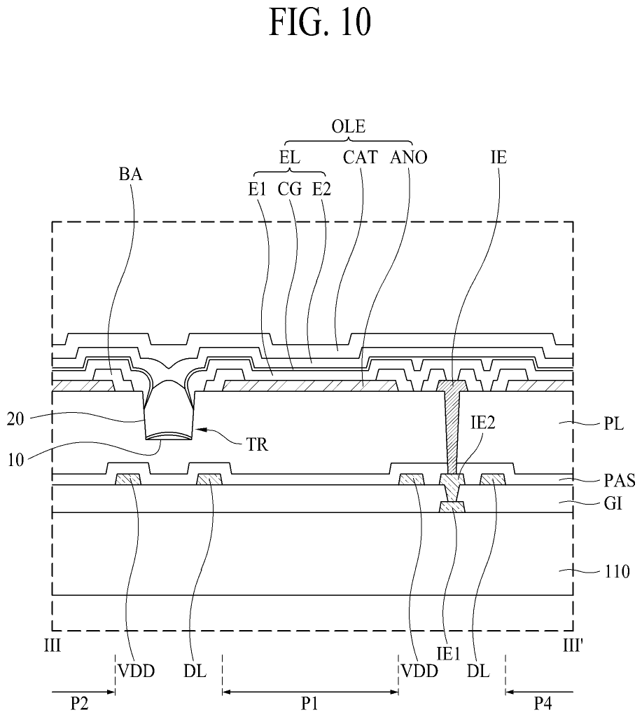

Hereinafter, referring to FIGS. 9 and 10, the second embodiment which is provided in order to prevent such a problem which can be raised in the structure explained in the first embodiment, will be described. FIG. 9 is a plane view illustrating a structure of 2X2 pixels in the electroluminescence display according to a second embodiment of the present disclosure. FIG. 10 is a cross-sectional view along to cutting line III-III′ in FIG. 9, for illustrating a structure of an electroluminescence display according to the second embodiment of the present disclosure.

As shown in FIG. 9, it will be described with pixels arranged in a 2×2 matrix structure. The first pixel P1 can be arranged in 1^{st} row and 1^{st} column, the second pixel P2 can be arranged in 1^{st} row and 2^{nd} column, the third pixel P3 can be arranged in 2^{nd} row and 1st column, and the fourth pixel P4 can be arranged in 2^{nd} row and 2^{nd} column. Each pixel can have rectangular shape including a first side 11, a second side 12 perpendicular to the first side 11, a third side 13 parallel to the first side 11 and a fourth side 14 parallel to the second side 12.

The trenches TR are disposed outside the four sides 11, 12, 13 and 14 of each pixel. In FIG. 9, the portion marked with a dotted square within the area of the pixel P represents the boundary line of the anode electrode ANO. The solid lines drawn inside and outside the boundary line of the anode electrode ANO represent one side and the other side of the bank BA. That is, the bank BA covers the edge of the anode electrode ANO. Trenches TR are respectively disposed each of between the bank BA of the first pixel P1 and the bank BA of the second pixel P2, between the bank BA of the first pixel P1 and the bank BA of the third pixel P3, between the bank BA of the second pixel P2 and the bank BA of the fourth pixel P4, and between the bank BA Of the third pixel P3 and the bank BA of the fourth pixel P4. The trench TR can include a vertical trench TRV disposed between banks BA covering two opposing sides of neighboring pixels adjacent along the X-axis direction, and a horizontal trench TRH disposed between banks BA covering two opposing sides of neighboring pixels adjacent along the Y-axis direction. The vertical trenches TRV may not be connected as one body, but can have separated line segment shapes in each pixel. The horizontal trenches TRH can have the same shape and structure.

For example, a first vertical trench TRV1 can be disposed between the first pixel P1 and the second pixel P2, and a second vertical trench TRV2 can be disposed between the third pixel P3 and the fourth pixel P4. Further, a first horizontal trench TRH1 can be disposed between the first pixel P1 and the third pixel P3, and a second horizontal trench TRH2 can be disposed between the second pixel P2 and the fourth pixel P4.

The first vertical trench TRV1 and the second vertical trench TRV2 can a same predetermined width, and the lengths same as or slightly longer than the corresponding vertical sides of the pixel. The first horizontal trench TRH1 and the second horizontal trench TRH2 can be a same predetermined width, and the lengths can be the same as or a little longer than the corresponding horizontal sides of the pixel.

At the intersection portion where the first vertical trench TRV1, the second vertical trench TRV2, the first horizontal trench TRH1 and the second horizontal trench TRH2 meet each other, an induction electrode IE can be disposed. The induction electrode IE is an electrode formed on the same layer and made of the same material as the anode electrode ANO. The induction electrode IE is an electrode layer that contacts the emission layer EL to discharge out the leakage current occurring between one pixel and a diagonally neighboring pixel. Also, the induction electrode IE can be disposed between the driving current line VDD and the data line DL.

Referring to FIG. 10, the emission layer EL can have the stacked structure at the trench as explained in the first embodiment. For example, after forming the trench TR, the first emission layer E1 can be deposited on the anode electrode ANO and the bank BA. On the bottom surface 10 of the trench TR, the first emission layer E1 can be deposited. On the side wall surface 20 of the trench TR, the first emission layer E1 may not cover all of the side wall surface 20 but can be stacked on top portions only. Therefore, the first emission layer E1 can be deposited on the whole surface of the substrate 110, but the connectivity of the first emission layer E1 can be disconnected by trench TR in pixel unit.

The charge generation layer CG can be deposited on the first emission layer E1. The charge generation layer CG can be stacked on the bottom surface 10 of the trench TR. On the side wall surface 20, the charge generation layer CG can be deposited only at the top portions. Accordingly, the charge generation layer CG can be deposited on the whole surface of the substrate 110, but the connectivity of the charge generation layer CG can be disconnected by trench TR in pixel unit.

The second emission layer E2 can be deposited on the charge generation layer CG. The second emission layer E2 thickened from the left side and the second emission layer E2 thickened from the right side can contact each other at the top portion of the trench TR, so that the upper space of the trench TR can be closed and a void space can exist thereunder. As the result, the second emission layer E2 can have a structure in which the second emission layer E2 can be connected over all pixels on the whole surface of the substrate 110.

The cathode electrode CAT can be deposited on the second emission layer E2. Since the second emission layer E2 has a structure connected between all pixels on the entire surface of the substate 110, the cathode electrode CAT also has a structure connected between all pixels.

On the other hand, the trench TR is not formed at the intersection portion CRO where the vertical trench TRV and the horizontal trench TRH intersect, but an induction electrode IE is formed on the planarization layer PL. The bank BA covers the edge of the induction electrode IE, and the central part of the induction electrode IE is exposed. After forming the bank BA, an emission layer EL is deposited. The emission layer EL is in direct contact with the induction electrode IE.

The induction electrode IE is an element for discharging out the horizontal current which is generated in the emission layer EL and transmitted to the neighboring pixel. Therefore, it is preferable that the induction electrode IE is connected to an induction line IE1. The induction line IE1 can be a line that runs along the X-axis direction or the Y-axis direction on the substrate 110. Since the scan line SL runs in the X-axis direction and the data line DL runs in the Y-axis direction on the substrate 110, the induction line IE1 can be formed on the same layer as the scan line SL which is a different layer from the data line DL, or on the same layer as the data line DL which is a different layer from the scan line SL.

For example, in order to dispose the induction line IE1 as running in the X-axis direction, the induction line IE1 can be placed on the substrate 110 and below the gate insulating layer GI which is the layer where the scan line SL is disposed. In addition, an intermediate electrode IE2 can be provided to facilitate the connection of the induction electrode IE with the induction line IE1. For example, the intermediate electrode IE2 can be disposed between the data line DL and the driving current line VDD disposed on the gate insulating layer GI. The induction electrode IE and the intermediate electrode IE2 can be connected by penetrating the passivation layer PAS and the planarization layer PL covering the intermediate electrode IE2. Additionally, the intermediate electrode IE2 can be connected to the induction line IE1 through a contact hole penetrating the gate insulating layer GI covering the induction line IE1.

As a result, leakage current can be blocked between neighboring pixels in the horizontal and vertical directions by the trenches TRH and TRV. At the same time, between diagonally neighboring pixels, leakage current can be discharged to the outside through the induction electrode IE and the induction line IE1. Accordingly, leakage current between neighboring pixels can be completely eliminated, deterioration in image quality can be prevented, and accurate image information can be provided.

In FIG. 9, which shows the second embodiment, the induction electrode IE is disposed at the intersection of two opposing horizontal trenches TRH1 and TRH2, and two opposing vertical trenches TRV1 and TRV2. Also, the present disclosure is not limited to this. An induction electrode can also be disposed at a portion where two horizontal trenches and one vertical trench intersect. Alternatively, an induction electrode can be placed at the intersection of one horizontal trench and two vertical trenches. Moreover, when it is desirable, an induction electrode can also be placed at the intersection of one horizontal trench and one vertical trench.

### Third Embodiment

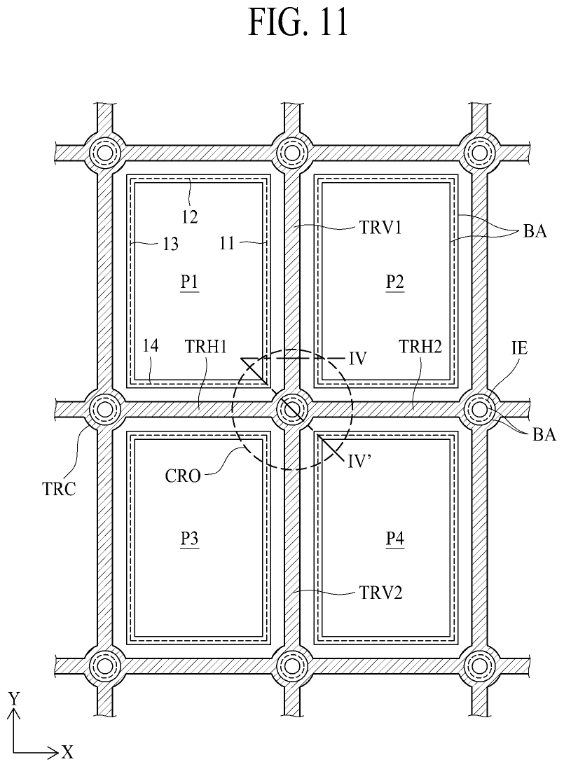

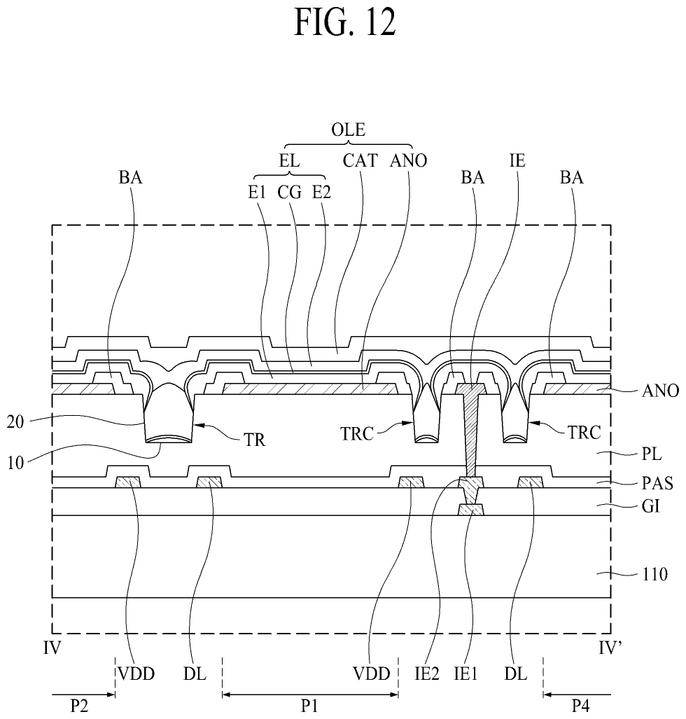

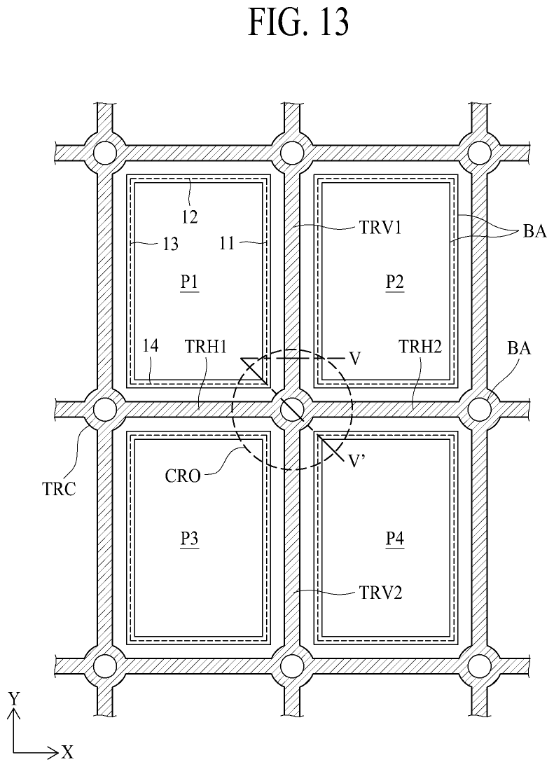

Hereinafter, referring to FIGS. 11 and 12, a third embodiment will be described. FIG. 11 is a plane view illustrating a structure of 2×2 pixels in the electroluminescence display according to a third embodiment of the present disclosure. FIG. 12 is a cross-sectional view, along to cutting line IV-IV′ in FIG. 11, illustrating a structure of an electroluminescence display according to the third embodiment of the present disclosure.

The third embodiment shown in FIG. 11 has almost the same structure as FIG. 9. which explains the second embodiment. The difference is that the light emitting display device according to the third embodiment is characterized in that a cross trench TRC is formed around the induction electrode IE. For example, the cross trench TRC can be a circular trench that completely surrounds the induction electrode IE at the intersection between four adjacent pixels, but embodiments are not limited thereto. For example, the cross trench TRC can have a polygon shape or a square shape, or a perforated shape etc.

The third embodiment will be explained with the arrangement of 2×2 matrix structure as shown in FIG. 9. A first pixel P1 is placed at 1-row and 1-column, a second pixel P2 is placed at 1-row and 2-column, a third pixel P3 is placed at 2-row and 1-column, and a fourth pixel P4 is placed at 2-row and 2-column. Each pixel has a rectangular shape including a first side 11, a second side 12 perpendicular to the first side 11, a third side 13 parallel to the first side 11, and a fourth side 14 parallel to the second side 12.

A bank BA is formed to cover the four sides 11, 12, 13 and 14 of each pixel. Trenches TR are arranged between banks BA and banks BA. The trench TR includes a vertical trench TRV and a horizontal trench TRH, in which the vertical trench TRV is disposed between banks BA covering two opposing sides of neighboring pixels in the X-axis direction, and the horizontal trench TRH is disposed between banks BA covering two opposing sides of neighboring pixels in the Y-axis direction.

For example, a first vertical trench TRV1 is disposed between the first pixel P1 and the second pixel P2. A second vertical trench TRV2 is disposed between the third pixel P3 and the fourth pixel P4. A first horizontal trench TRH1 is disposed between the first pixel P1 and the third pixel P3. A second horizontal trench TRH2 is disposed between the second pixel P2 and the fourth pixel P4.

A cross trench TRC and an induction electrode IE are formed at an intersection portion CRO where the first vertical trench TRV1 and the second vertical trench TRV2 face each other, and the first horizontal trench TRH1 and the second horizontal trench TRH2 face each other. The cross trench TRC is placed at the area where the vertical trench TRV and the horizontal trench TRH are crossing each other or meet with each other. The cross trench TRC has a structure like a revolving intersection connecting the vertical trench TRV and the horizontal trench TRH (e.g., the cross trench TRC can have a shape similar to a vehicular roundabout intersection).

For example, the cross trench TRC can be formed at the intersection portion CRO where the first vertical trench TRV1, the second vertical trench TRV2, the first horizontal trench TRH1 and the second horizontal trench TRH1 are met. The cross trench TRC can have a circle shape.

Further, an induction electrode IE is disposed at the center of the cross trench TRC. The induction electrode IE can have a circular shape or a rounded shape. Alternatively, the cross trench TRC can have a perforated disk shape or a donut shape surrounding the induction electrode IE.

The induction electrode IE can be an electrode formed on the same layer and made of the same material as the anode electrode ANO. The bank BA can cover the edge of the induction electrode IE. The central portion of the induction electrode IE is not covered by the bank BA but exposed. The induction electrode IE is an electrode layer that contacts the emission layer EL to discharge out the leakage current occurring between one pixel and a diagonally neighboring pixel.

Referring to FIG. 12, in the trench TR, the emission layer EL has the same structure as described in the second embodiment. For example, with the trench TR formed, the first emission layer E1 is deposited on the anode electrode ANO and the bank BA. The first emission layer E1 is deposited on the entire surface of the substrate 110, but its connectivity is interrupted by the trench TR, so that the first emission layer E1 is separated on the unit of pixel.

A charge generation layer CG is stacked on the first emission layer E1. The charge generation layer CG is also deposited on the entire surface of the substrate 110, but its connectivity is interrupted by the trench TR, so that the charge generation layer CG is also separated on the unit of pixel. A second emission layer E2 is stacked on the charge generation layer CG. The second emission layer E2 can has a structure connected between all pixels on the entire surface of the substrate 110. A cathode electrode CAT is stacked on the second emission layer E2. Since the second emission layer E2 has a structure connected between all pixels on the entire surface of the substrate 110, the cathode electrode CAT also has a structure connected between all pixels.

Meanwhile, a cross trench TRC is formed at the intersection portion CRO where the vertical trench TRV and the horizontal trench TRH are crossing each other. The cross-sectional structure of the cross trench TRC also has the same structure as the vertical trench TRV and the horizontal trench TRH. Additionally, an induction electrode IE formed on the planarization layer PL is formed in the central area of the cross trench TRC. The bank BA covers the edge of the induction electrode IE, but the central portion of the induction electrode IE is exposed. After forming the bank BA, the emission layer EL is deposited. The emission layer EL is in direct contact with the induction electrode IE.

In the third embodiment, since the induction electrode IE is disposed at the central portion of the cross trench TRC, the width of the cross trench TRC can be narrower than the widths of the vertical trench TRV and the horizontal trench TRH. Therefore, unlike the situation described with reference to FIGS. 7 and 8, defects in the light emitting diode OLE by the cross trench TRC can be prevented.

On the other hand, when the width of the cross trench TRC is excessively narrower than the widths of the vertical trench TRV and the horizontal trench TRH, the charge generation layer CG is not effectively cut off by the cross trench TRC, so that the leakage current may flow through the charge generation layer CG. However, in the third embodiment, the induction electrode IE is disposed in the center of the cross trench TRC, so that if any leakage current does occur, it is discharged to the outside through the induction electrode IE and the induction line IE1.

The induction electrode IE is an element for discharging out the horizontal current which is generated in the emission layer EL and transmitted to the neighboring pixel. Therefore, it is preferable that the induction electrode IE is connected to an induction line IE1. For example, in order to dispose the induction line IE1 as running in the X-axis direction, the induction line IE1 can be placed on the substrate 110 and below the gate insulating layer GI which is the layer where the scan line SL is disposed.

In addition, an intermediate electrode IE2 can be provided to facilitate the connection of the induction electrode IE with the induction line IE1. For example, the intermediate electrode IE2 can be disposed between the data line DL and the driving current line VDD disposed on the gate insulating layer GI. The induction electrode IE and the intermediate electrode IE2 can be connected by penetrating the passivation layer PAS and the planarization layer PL covering the intermediate electrode IE2. Additionally, the intermediate electrode IE2 can be connected to the induction line IE1 through a contact hole penetrating the gate insulating layer GI covering the induction line IE1.

As a result, leakage current can be blocked between neighboring pixels in the horizontal and vertical directions by the trenches TRH and TRV. At the same time, between diagonally neighboring pixels, leakage current can be blocked by the cross trench TRC or discharged to the outside through the induction electrode IE and the induction line IE1. Accordingly, any leakage current between neighboring pixels can be completely eliminated, deterioration in image quality can be prevented, and accurate image information can be provided.

In FIG. 11, which shows the third embodiment, the induction electrode IE is disposed at the intersection of two opposing horizontal trenches TRH1 and TRH2, and two opposing vertical trenches TRV1 and TRV2. Also, the present disclosure is not limited to this. An induction electrode can also be disposed at a portion where two horizontal trenches and one vertical trench intersect. Alternatively, an induction electrode can be placed at the intersection of one horizontal trench and two vertical trenches. Moreover, when it is desirable, an induction electrode can also be placed at the intersection of one horizontal trench and one vertical trench.

### Fourth Embodiment

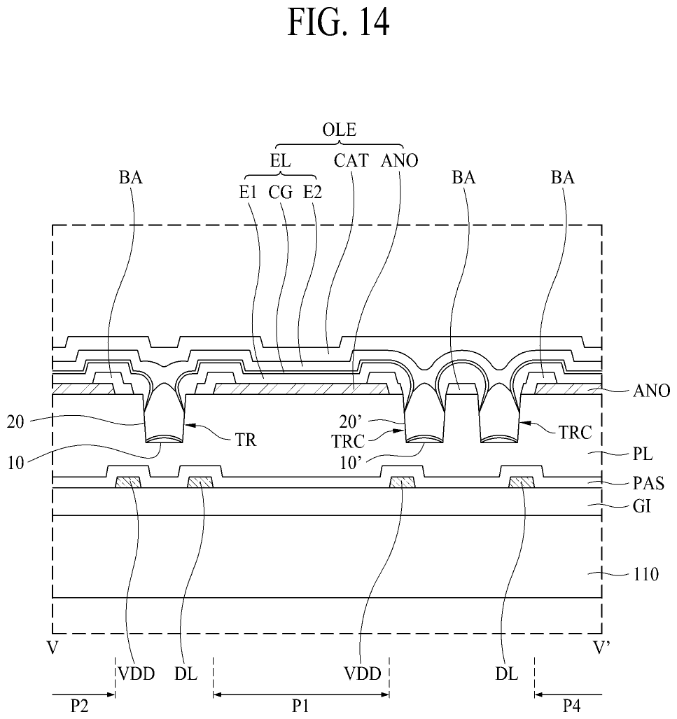

Hereinafter, referring to FIGS. 13 and 14, a fourth embodiment will be described. FIG. 13 is a plane view illustrating a structure of 2×2 pixels in the electroluminescence display according to a fourth embodiment of the present disclosure. FIG. 14 is a cross-sectional view, along to cutting line V-V′ in FIG. 11, illustrating a structure of an electroluminescence display according to the fourth embodiment of the present disclosure.

The light emitting display device according to the fourth embodiment has a very similar structure to the light emitting display device according to the third embodiment, except it does not include an induction electrode IE between four adjacent pixels. The light emitting display device according to the third embodiment has a structure in which an induction electrode IE and a cross trench TR are disposed at a portion where the horizontal trenches TRH1 and TRH2 meet the vertical trenches TRV1 and TRV2. The light emitting display device according to the fourth embodiment has a structure excluding the induction electrode IE from the structure of the third embodiment.

In the fourth embodiment, a cross trench TRC having a perforated circle shape or donut shape is formed at the intersection portion of the horizontal trenches TRH1 and TRH2 meeting the vertical trenches TRV1 and TRV2. However, there is no clement in the central portion of the cross trench TRC, such as an induction electrode, for discharging lateral leakage current to the outside by contacting the emission layer EL and/or the charge generation layer CG.

In this situation, it is preferable that the width of the cross trench TRC is formed to have the same width as the width of the horizontal trenches TRH1 and TRH2 and the vertical trenches TRV1 and TRV2. To do so, in the cross trench TRC, the connectivity of the first emission layer E1 and the charge generation layer CG can be disconnected or cut on the unit of pixel, as in the horizontal trenches TRH1 and TRH2 and the vertical trenched TRV1 and TRV2. For example, the first emission layer E1 and the charge generation layer CG are stacked on the bottom surface 10′ of the cross trench TRC, but are not completely stacked on the side surface 20′ and are partially stacked only on the top surface. Accordingly, the first emission layer E1 and the charge generation layer CG are deposited on the entire surface of the substrate 110, but their connectivity is also interrupted by the cross trench TRC. As a result, it is possible to prevent the problem of lateral leakage current occurring at the intersection as described with FIG. 8. In other words, the structure of the cross trench TRC avoids it from becoming too wide and prevents over etching problem discussed in relation to FIG. 8.

In FIG. 13, which shows the fourth embodiment, the cross trench TRC is disposed at the intersection of two opposing horizontal trenches TRH1 and TRH2, and two opposing vertical trenches TRV1 and TRV2. Also, the present disclosure is not limited to this. A cross trench can also be disposed at a portion where two horizontal trenches and one vertical trench intersect. Alternatively, a cross trench can be placed at the intersection of one horizontal trench and two vertical trenches. Moreover, when it is necessary, a cross trench can also be placed at the intersection of one horizontal trench and one vertical trench. Furthermore, the cross trench can be formed in a polygonal shape surrounding a polygonal shaped bank pattern located inside the cross trench. Alternatively, the cross trench can be formed to surround only a portion of the polygonal shaped bank pattern located inside the cross trench.

The features, structures, effects and so on described in the above examples of the present disclosure are included in at least one example of the present disclosure, and are not limited to only one example. Furthermore, the features, structures, effects and the likes explained in at least one example can be implemented in combination or modification with respect to other examples by those skilled in the art to which this disclosure belongs. Accordingly, contents related to such combinations and variations should be construed as being included in the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. An electroluminescence display comprising:
a first pixel disposed at 1^{st} row-1^{st} column, a second pixel disposed at 1^{st} row-2^{nd} column, a third pixel disposed at 2^{nd} row-1^{st} column, and a fourth pixel disposed at 2^{nd} row-2^{nd} column, on a substrate;
a first vertical trench disposed between the first pixel and the second pixel;
a second vertical trench disposed between the third pixel and the fourth pixel;
a first horizontal trench disposed between the first pixel and the third pixel;
a second horizontal trench disposed between the second pixel and the fourth pixel; and
an induction electrode disposed at an intersection portion where the first vertical trench and the second vertical trench face each other, and the first horizontal trench and the second horizontal trench face each other.

2. The electroluminescence display according to claim 1, further comprising:
a first emission layer disposed in the first, second, third and fourth pixels, the first emission layer being disconnected by the first vertical trench, the second vertical trench, the first horizontal trench and the second horizontal trench, and connected to the induction electrode;
a charge generation layer disposed on the first emission layer, the charge generation layer being disconnected by the first vertical trench, the second vertical trench, the first horizontal trench and the second horizontal trench, and continuously extending over opposite sides of the induction electrode; and
a second emission layer disposed on the charge generation layer, the second emission layer continuously extending over the first vertical trench, the second vertical trench, the first horizontal trench, the second horizontal trench, and the induction electrode.

3. The electroluminescence display according to claim 2, further comprising:
a plurality of first electrodes disposed in the first, second, third and fourth pixels; and
a second electrode disposed on the second emission layer, the second electrode continuously extending over the first vertical trench, the second vertical trench, the first horizontal trench, the second horizontal trench, and the induction electrode.

4. The electroluminescence display according to claim 3, wherein the induction electrode is disposed at a same layer and made of a same material as the plurality of first electrodes.

5. The electroluminescence display according to claim 4, further comprising:
an induction line disposed between the substrate and the first vertical trench, the second vertical trench, the first horizontal trench and the second horizontal trench,
wherein the induction electrode is electrically connected to the induction line.

6. The electroluminescence display according to claim 5, further comprising:
an intermediate electrode connected between the induction electrode and the induction line.

7. The electroluminescence display according to claim 1, further comprising:
a cross trench at an intersection portion where the first vertical trench, the second vertical trench, the first horizontal trench and the second horizontal trench meet with each other,
wherein the induction electrode is disposed at a central area of the cross trench.

8. An electroluminescence display comprising:
a planarization layer disposed on a substrate;
a first electrode disposed on the planarization layer, the first electrode including a first side, a second side perpendicular to the first side, and an intersection portion where the first side meets with the second side;
a trench disposed outside of the first side and the second side of the first electrode, the trench having a predetermined width;
an induction electrode disposed at the intersection portion;
a first emission layer disposed on the first electrode, the first emission layer being disconnected by the trench, and electrically connected to the induction electrode;
a charge generation layer disposed on the first emission layer, the charge generation layer being disconnected by the trench, and continuously extending over opposite sides of the induction electrode;
a second emission layer disposed on the charge generation layer, the second emission layer continuously extending over both of the trench and the induction electrode; and
a second electrode disposed on the second emission layer, the second electrode continuously extending over both of the trench and the induction electrode.

9. The electroluminescence display according to claim 8, wherein the charge generation layer is electrically disconnected from the cathode electrode in the trench.

10. The electroluminescence display according to claim 8, wherein the first electrode further includes:
a third side parallel to the first side; and
a fourth side parallel to the second side, and
wherein the trench includes:
a first trench disposed outside of the first side and the third side; and
a second trench disposed outside of the second side and the fourth side.

11. The electroluminescence display according to claim 10, further comprising:
a bank including a first bank portion and a second bank portion,
wherein the first bank portion covers the first side, the second side, the third side and the fourth side of the first electrode, and exposes a central portion of the first pixel,
wherein the second bank portion covers edge portions of the induction electrode and exposes a central portion of the induction electrode, and
wherein the trench extends through the bank and extends at least partially into the planarization layer.

12. The electroluminescence display according to claim 8, wherein the first electrode further includes:
a third side parallel to the first side; and
a fourth side parallel to the second side,
wherein the trench includes:
a first trench disposed along the first side of the first electrode;
a second trench disposed along the second side of the first electrode;
a third trench disposed along the third side of the first electrode; and
a fourth trench along the fourth side of the first electrode,
wherein the induction electrode has a rectangular shape including four sides corresponding the first, second, third and fourth trenches, respectively.

13. The electroluminescence display according to claim 8, wherein the induction electrode is disposed at a same layer and includes a same material as the first electrode.

14. The electroluminescence display according to claim 8, further comprising:
a cross trench surrounding the induction electrode and connected to the trench.

15. The electroluminescence display according to claim 14, wherein a width of the cross trench is narrower than a width of the trench.

16. The electroluminescence display according to claim 14, wherein the first emission layer is disconnected by the cross trench,
wherein the charge generation layer is disconnected by the cross trench,
wherein the second emission layer continuously extends over the cross trench, and
wherein the second electrode continuously extends over the cross trench.

17. The electroluminescence display according to claim 14, wherein the cross trench has a circular shape or a closed loop shape.

18. The electroluminescence display according to claim 8, further comprising:
an induction line disposed between the planarization layer and on the substrate, and electrically connected to the induction electrode.

19. The electroluminescence display according to claim 18, further comprising:
an intermediate electrode connected between the induction electrode and the induction line.

20. A display device comprising:
a first pixel and a second pixel adjacent to the first pixel;
a trench disposed between the first pixel and the second pixel; and
an emission layer disposed on the first pixel and the second pixel, the emission layer including a plurality of layers,
wherein a first layer among the plurality of layers of the emission layer is disconnected in an area corresponding to the trench.

21. The display device according to claim 20, wherein a second layer among the plurality of layers of the emission layer continuously extends across opposite sides of the trench.

22. The display device according to claim 20, further comprising:
a third pixel adjacent to the first pixel;
a fourth pixel adjacent to the third pixel and the second pixel; and
an induction electrode disposed between the first, second, third and fourth pixels,
wherein the induction electrode is electrically connected to the emission layer.

23. The display device according to claim 22, wherein all of the layers among the plurality of layers of the emission layer continuously extend across opposite sides of the induction electrode.

24. The display device according to claim 20, further comprising:
a third pixel adjacent to the first pixel;
a fourth pixel adjacent to the third pixel and the second pixel; and
a cross trench disposed between the first, second, third and fourth pixels.

25. The display device according to claim 24, further comprising:
an induction electrode disposed between the first, second, third and fourth pixels, the induction electrode being electrically connected to the emission layer,
wherein the cross trench at least partially surrounds the induction electrode.

26. The display device according to claim 25, wherein the cross trench has a closed loop shape that surrounds the induction electrode.

27. The display device according to claim 24, wherein a width of the cross trench is less than or equal to a width of the trench.

28. The display device according to claim 24, wherein the cross trench is connected to or in communication with the trench.

29. The display device according to claim 20, wherein the trench is disposed between a data line and a power line.
